(19) United States
(12) Patent Application Publication
(10) Pub. No.: US 2026/0040454 A1
(43) Pub. Date: Feb. 5, 2026

(54) Power Module

(71) Applicants: HYUNDAI MOTOR COMPANY, Seoul (KR); KIA CORPORATION, Seoul (KR)

(72) Inventors: Kyung Min Kim, Hwaseong-si (KR); Ji Hwan Lim, Hwaseong-si (KR)

(73) Assignees: HYUNDAI MOTOR COMPANY, Seoul (KR); KIA CORPORATION, Seoul (KR)

(21) Appl. No.: 19/052,859

(22) Filed: Feb. 13, 2025

(30) Foreign Application Priority Data
Jul. 30, 2024 (KR) 10-2024-0101045

(51) Int. Cl. H05K 1/18; H02M 3/00; H02M 7/00

(52) U.S. Cl. CPC H05K 1/18; H02M 3/003; H02M 7/003

(57) ABSTRACT

A power module is disclosed. The power module includes a connector pin configured to receive an electrical signal, and a pin holder formed, at upper and lower surfaces thereof, with an upper insertion hole and a lower insertion hole configured to receive the connector pin, respectively. Each of the upper insertion hole and the lower insertion hole surface-contacts or line-contacts surfaces or edges of the connector pin, thereby supporting the connection pin inserted thereinto while regulating an insertion direction of the connector pin. The surfaces or the edges supported by the upper insertion hole are different from the surfaces or the edges supported by the lower insertion hole.

### CROSS-REFERENCE TO THE RELATED APPLICATION(S)

This application claims priority from Korean Patent Application No. 10-2024-0101045 filed on Jul. 30, 2024, in the Korean Intellectual Property Office, the disclosure of which is incorporated herein by reference in its entirety.

### TECHNICAL FIELD

The present disclosure relates to a power module.

### BACKGROUND

A power module is an electronic device used for control and conversion of electric power. Such a power module mainly adjusts or converts voltage/current or electric power. For example, the power module is used in a device such as a DC-DC converter, an AC-DC converter, and/or an inverter, to achieve (e.g., efficient) energy conversion and power management.

Meanwhile, in association with electric vehicles, need of a power conversion device satisfying (e.g., high) output power and (e.g., high) efficiency in order to achieve an increase in driving range is increasing.

Meanwhile, when the number of power modules increases, the number of pins for transmission of a signal to the power modules is increased and, as such, the number of pins to be assembled to a board is increased. Since automation of assembly and production is a current trend in power modules, an increase in the number of pins may cause automatic assembly to be difficult. Furthermore, when positions (e.g., of a part) of pins are misaligned in a procedure of assembling the pins to the board, the board and the pins may be damaged. As a result, the number of processes and the time required for production of a power conversion device may be (e.g., greatly) increased.

The above matters disclosed in this section are for the understanding of the general background of the disclosure and should not be taken as an acknowledgment or any form of suggestion that the matters form the related art already known to a person skilled in the art.

### SUMMARY

Therefore, the present disclosure has been made in view of the above problems, and it is an object of the present disclosure to provide a power module configured to achieve automatic assembly thereof while preventing erroneous positioning of connector pins.

Objects of the present disclosure are not limited to the above-described objects, and other objects of the present disclosure not yet described will be more clearly understood by those skilled in the art from the following detailed description.

In accordance with an aspect of the present disclosure, the above and other objects can be accomplished by the provision of a power module including a connector pin configured to receive an electrical signal, and a pin holder formed, at upper and lower surfaces thereof, with an upper insertion hole and a lower insertion hole configured to receive the connector pin, respectively, wherein each of the upper insertion hole and the lower insertion hole surface-contacts or line-contacts surfaces or edges of the connector pin, thereby supporting the connection pin inserted thereinto while regulating an insertion direction of the connector pin, and the surfaces or the edges supported by the upper insertion hole are different from the surfaces or the edges supported by the lower insertion hole.

The surfaces of the connector pin supported by the upper insertion hole or the lower insertion hole may face each other.

The edges of the connector pin supported by the upper insertion hole or the lower insertion hole have a diagonal relation.

The connection pin may have a quadrangular cross-sectional shape.

The upper insertion hole or the lower insertion hole may have a quadrangular cross-sectional shape.

The cross-sectional area of an overlap portion between the upper insertion hole and the lower insertion hole may be smaller than the cross-sectional area of the upper insertion hole or the lower insertion hole.

The cross-sectional area of the overlap portion between the upper insertion hole and the lower insertion hole may be greater than or equal to the cross-sectional area of the connector pin.

A slope may be formed at at least one of the upper insertion hole or the lower insertion hole to be inclined inwards to guide an initial insertion direction of the connector pin.

The surfaces or the edges of the connector pin may be supported by contact portions of the upper insertion hole or the lower insertion hole, and each of the contact portions may have a cross-sectional area smaller than or equal to the cross-sectional area of the slope.

A plurality of upper insertion holes and a plurality of lower insertion holes may be formed at the upper and lower surfaces of the pin holder.

A space may be formed at a middle portion of the pin holder between the upper and lower surfaces of the pin holder.

In accordance with another aspect of the present disclosure, there is provided a power module including a connector pin configured to receive an electrical signal, and a pin holder formed, at upper and lower surfaces thereof, with an upper insertion hole and a lower insertion hole, respectively, wherein each of the upper insertion hole and the lower insertion hole supports one surface of the connector pin and an edge of the connector pin facing the surface to regulate an insertion direction of the connector pin, and the surface and the edge supported by the upper insertion hole are different from the surface and the edge supported by the lower insertion hole, respectively.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 shows connector pins and a pin holder in a power module according to an embodiment of the present disclosure;

FIG. 2 shows a state in which a plurality of connector pins is inserted into the pin holder;

FIG. 3 shows a procedure before insertion of the connector pin;

FIG. 4 shows insertion of the connection pin up to the lower insertion hole;

FIG. 5 shows a cross-section taken along line A-A of FIG. 4;

FIG. 6 shows a cross-section taken along line B-B of FIG. 4;

FIG. 7 shows insertion of the connector pin up to the upper insertion hole;

FIG. 8 shows a cross-section taken along line C-C in FIG. 7;

FIGS. 9 and 10 show a state of the pin holder into which the connector pins have been completely inserted, when viewed at a top side; and

FIGS. 11 and 12 show a series of procedures of inserting the connector pins.

### DETAILED DESCRIPTION

Hereinafter, embodiments of the present disclosure will be described in detail with reference to the accompanying drawings, and the same or similar elements are designated by the same reference numerals regardless of the numerals in the drawings and redundant description thereof will be omitted.

In the following description of the embodiments of the present disclosure, a detailed description of known functions and configurations incorporated herein will be omitted when it may obscure the subject matter of the embodiments of the present disclosure. In addition, the embodiments of the present disclosure will be more clearly understood from the accompanying drawings and should not be limited by the accompanying drawings, and it is to be appreciated that all changes, equivalents, and substitutes that do not depart from the spirit and technical scope of the present disclosure are encompassed in the present disclosure.

It will be understood that, although the terms “first”, “second”, and the like may be used herein to describe various elements, these elements should not be limited by these terms. These terms are (e.g., only) used to distinguish one element from another.

Unless clearly used otherwise, singular expressions include a plural meaning.

In this specification, the term “comprising”, “including”, or the like, is intended to express the existence of the characteristic, the numeral, the step, the operation, the element, the part, or the combination thereof, and does not exclude another characteristic, numeral, step, operation, element, part, or any combination thereof, or any addition thereto.

Although “module” or “unit” is suffixed to constituent elements described in the following description, this is intended (e.g., only) for ease of description of the specification. The suffixes themselves have no meaning or function to distinguish the constituent element using the suffix from the constituent element using no suffix.

In the case where an element is “connected” or “linked” to another element, it should be understood that the element may be directly connected or linked to the other element, or another element may be present therebetween. Conversely, in the case where an element is “directly connected” or “directly linked” to another element, it should be understood that no other element is present therebetween.

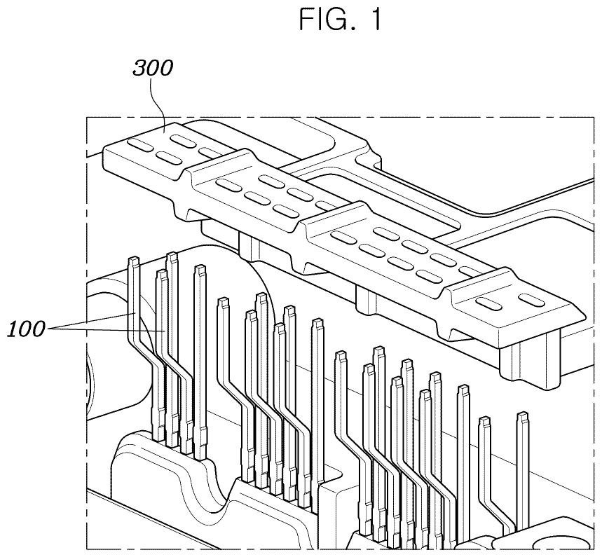

FIG. 1 shows connector pins 100 and a pin holder 300 in a power module according to an embodiment of the present disclosure. Referring to FIG. 1, each connector pin 100, which receives an electrical signal, extends in a longitudinal direction and is electrically connected to a board such as a printed circuit board (PCB).

The connector pins 100 may be electrically connected, one by one, to the board through a manual task of an operator. However, the recent tendency of a power conversion device is to have an increased number of connector pins 100 due to an increase in the number of power modules in the power conversion device. Furthermore, in accordance with a trend of automation of a production process by virtue of appearance of a smart factory, electrical connection of the connector pins 100 to the board may also be automatically carried out.

For automation of electrical connection of the connector pins 100 to the board, accuracy of positioning of the connector pins 100 should be considered (e.g., secured). That is, when an unacceptable tolerance is generated in association with positioning of the connector pins 100, a possibility that it may be difficult to achieve an automatic assembly process for the connector pins 100 may increase. To this end, the pin holder 300 may be included in the power module, for security of accuracy of positioning of the connector pins 100.

Basically, the pin holder 300 is configured to enable (e.g., correct) positioning of the connector pins 100 for electrical connection of the connector pins 100 to the board and to prevent (e.g., correct) positions of the connector pins 100 from being changed.

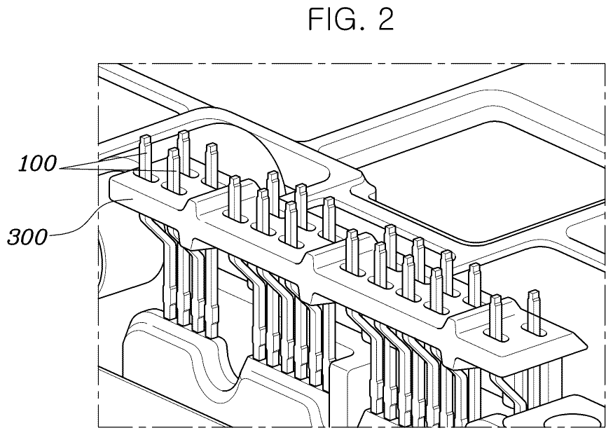

FIG. 2 shows a state in which a plurality of connector pins are inserted into the pin holder. When a plurality of connector pins 100 are inserted into the pin holder 300 in an aligned state, a process for electrical connection between the connector pins 100 and the board may be carried out.

Meanwhile, in a pin holder, which is conventionally used, insertion holes, into which connector pins will be inserted, respectively, have an inner diameter substantially equal to an outer diameter of the connector pins. Accordingly, the connector pins are (e.g., simultaneously) fixed to the pin holder in such a manner that each insertion hole contacts the (e.g., entire) surface of a corresponding one of the connection pins.

This method may have an advantage in that the connector pins are stably fixed, so long as alignment of (e.g., all) connector pins (e.g., is perfect to) enable the connector pins to be stably inserted into the pin holder. However, when any one of the connector pins is misaligned from a corresponding one of the insertion holes of the pin holder, the connector pin may not be properly inserted into the corresponding insertion hole. In this procedure, there may be a problem of bending of the connector pin, due to the weight of the pin holder.

In order to solve such a problem, in accordance with the present disclosure, the pin holder 300 is formed, at upper and lower surfaces thereof, with upper insertion holes 310 and lower insertion holes 330, into which the connector pins 100 will be inserted, respectively. Each of the upper insertion holes 310 and the lower insertion holes 330 may surface-contact or line-contact a surface or an edge of a corresponding one of the connector pins 100 to support the connector pin 100 and, as such, may regulate an insertion direction of the connector pin 100.

The present disclosure has a feature in that the upper insertion hole 310 or the lower insertion hole 330 supports at least one of the surface or the edge of the connector pin 100. In addition, the present disclosure has a feature in that the surfaces or the edges of the connector pin 100 respectively supported by the upper insertion hole 310 and the lower insertion hole 330 are different from each other.

In this case, each of the upper insertion hole 310 and the lower insertion hole 330 is provided with a contact portion configured to surface-contact or line-contact the connector pin 100. At least one of the surface or the edge of the connector pin 100 contacts the contact portion. The contact portion is formed to have a predetermined thickness (e.g., or more), thereby supporting at least one of the surface or the edge of the connector pin 100 and, as such, fixing the connector pin 100.

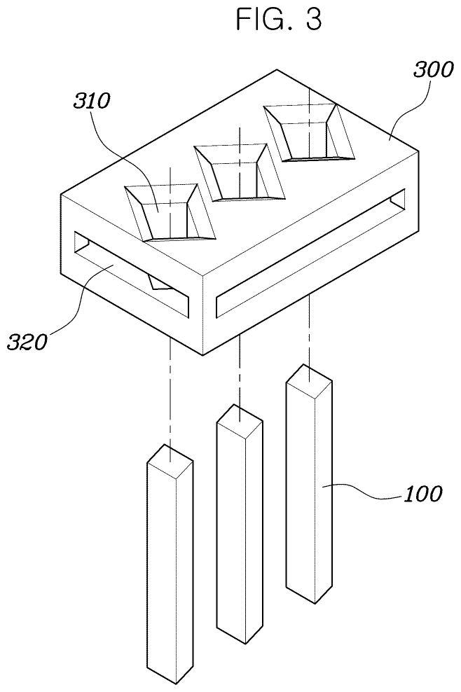

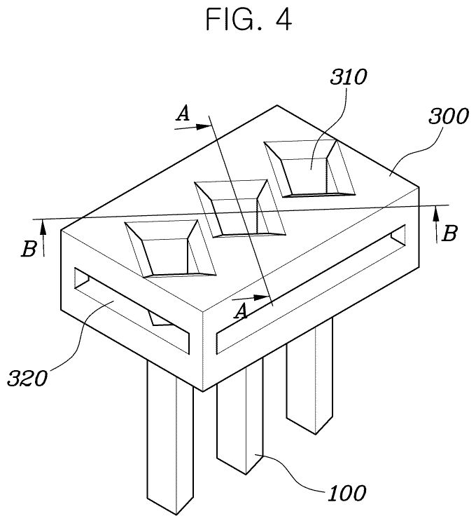

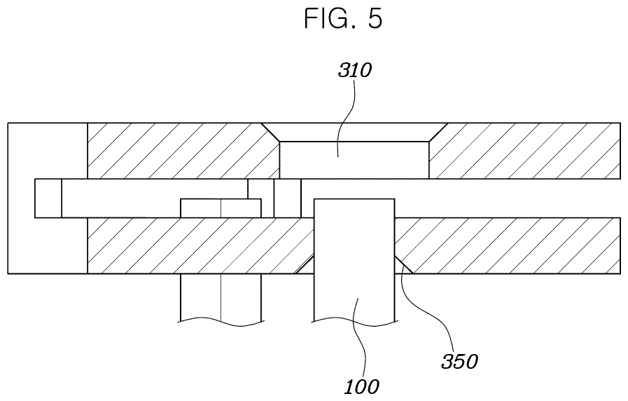

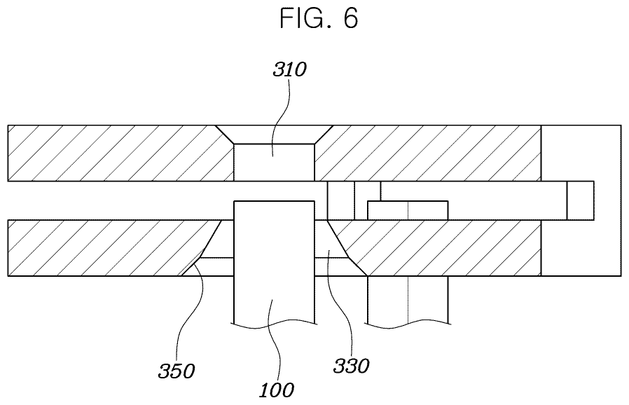

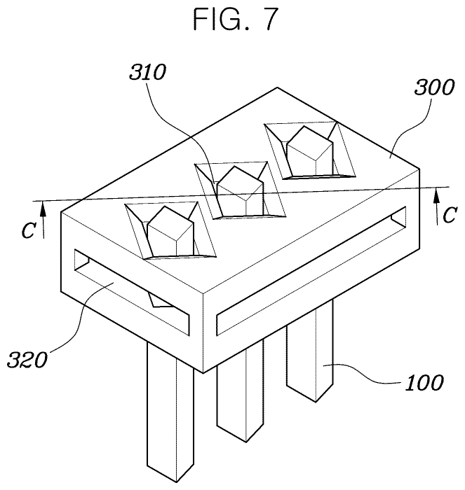

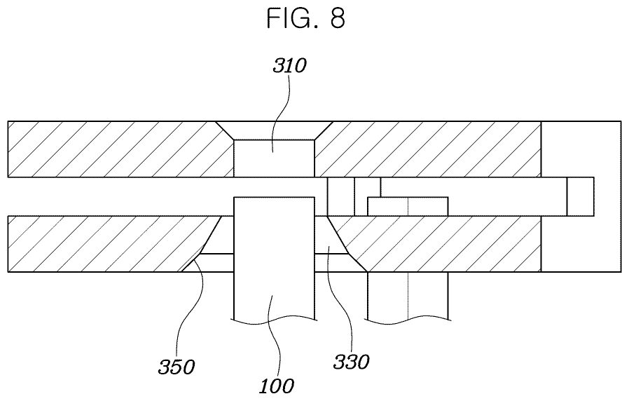

FIGS. 3 to 8 show a procedure in which one connector pin is inserted into the pin holder in accordance with an embodiment of the present disclosure. In detail, FIG. 3 shows a procedure before insertion of the connector pin, FIG. 4 shows insertion of the connection pin up to the lower insertion hole, and FIG. 7 shows insertion of the connector pin up to the upper insertion hole. FIGS. 5 and 6 show cross-sections taken along line A-A and line B-B in FIG. 4, respectively. FIG. 8 shows a cross-section taken along line C-C in FIG. 7.

The present disclosure will be described in more detail with reference to FIGS. 3 to 8. Referring to FIG. 3, the cross-section of the connector pin 100 has a quadrangular shape, and the cross-sections of the upper insertion hole 310 and the lower insertion hole 330 also have quadrangular shapes, respectively. However, these shapes are (e.g., only) illustrative. The cross-section of the connector pin 100 may have a circular shape, the cross-sections of the upper insertion hole 310 and the lower insertion hole 330 may also have circular shapes (or oval shapes), respectively. The cross-sections of the upper insertion hole 310 and the lower insertion hole 330 may have quadrangular shapes, respectively, and the cross-section of the connector pin 100 may have a circular shape. In addition, the cross-sections of the upper insertion hole 310 and the lower insertion hole 330 may have circular shapes, respectively, and the cross-section of the connector pin 100 may have a quadrangular shape.

That is, the connector pin 100 and the insertion holes 310 and 330 may have the same cross-sectional shape or may have different cross-sectional shapes. When the connector pin 100 and the upper and lower insertion holes 310 and 330 have the same cross-sectional shape, the upper and lower insertion holes 310 and 330 may support one surface of the connector pin 100 or an edge of the connector pin 100. On the other hand, when the connector pin 100 and the upper and lower insertion holes 310 and 330 have different cross-sectional shapes, the upper and lower insertion holes 310 and 330 may support an edge of the connector pin 100.

Although the upper insertion hole 310 and the lower insertion hole 330 may have the same cross-sectional shape, it should be understood that formation of the upper insertion hole 310 and the lower insertion hole 330 having different cross-sectional shapes falls within a possible category.

Of course, the cross-sectional shapes of the insertion holes 310 and 330 and the connector pin 100 may be diverse, as described above. For convenience of description, however, the case in which the cross-section of the connector pin 100 and the cross-sections of the upper insertion hole 310 and the lower insertion hole 330 have quadrangular shapes, respectively, will be described as a representative embodiment. In addition, the case in which each contact portion line-contacts an edge of the connector pin 100, thereby supporting the connector pin 100, will be described.

The connector pins 100 are aligned with the pin holder 300, as shown in FIG. 3. In addition, the connector pins 100 are inserted into the lower insertion holes 330 formed at the lower surface of the pin holder 300, respectively, as shown in FIG. 4, and are subsequently inserted into the upper insertion holes 310 formed at the upper surface of the pin holder 300, respectively, as shown in FIG. 7.

Referring to FIG. 5, it may be seen that two edges of the connector pin 100 are supported by respective contact portions of the lower insertion hole 330 when viewed with reference to the cross-section taken along line A-A in FIG. 4, whereas, referring to FIG. 6, it may be seen that two remaining edges of the connector pin 100 do not contact the contact portions of the lower insertion hole 330 when viewed with reference to the cross-section taken along line B-B in FIG. 4.

Referring to FIG. 8, it may be seen that the two remaining edges not contacting the contact portions of the lower insertion hole 300 contact respective contact portions of the upper insertion hole 310 when viewed with reference to the cross-section taken along line C-C in FIG. 7.

When the above-described coupling method is used, it may be possible to achieve fixing of the connector pin 100 because (e.g., all) edges of the connector pin 100 are supported by the lower insertion hole 330 and the upper insertion hole 310 in a divisional manner. In addition, it may be possible to more easily assembly the pin holder 300 because a part of the edges is first supported, and the remaining edges are then supported, as compared to the method in which (e.g., all of) the edges are supported at once. That is, the connector pin 100 may be easily inserted into the lower insertion hole 330 and, as such, a portion thereof may be fixed, so long as the edges of the connector pin 100, which will be supported by the lower insertion hole 330, are positioned at correct positions. Accordingly, the position of the connector pin 100 may be fixed to some extent and, as such, insertion of the connector pin 100 up to the upper insertion hole 310 may be freely guided.

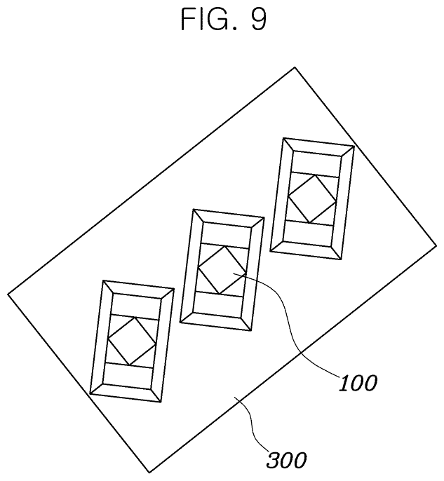

FIG. 9 may show the state of FIG. 8 in which insertion of the connector pin 100 is achieved through the above-described procedure, when viewed at a top side.

In the power module according to the present disclosure, through the pin holder 300, which has a layered structure, it may be possible to achieve excellent fixing of the connector pin 100 because, although edges of the connector pin 100 respectively supported by a lower layer and an upper layer of the pin holder 300 are different from each other, (e.g., all of) the edges of the connector pin 100 are finally supported by the connector pin 100. In addition, insertion of the connector pins 100 may be effectively guided by the lower insertion holes 330 even when a part of the connector pins 100 is misaligned from the pin holder 300, because, in a procedure of inserting each connector pin 100, the pin holder 300 sequentially supports points of the connector pin 100, to be supported, in a divisional manner, without supporting (e.g., all of) the points at once.

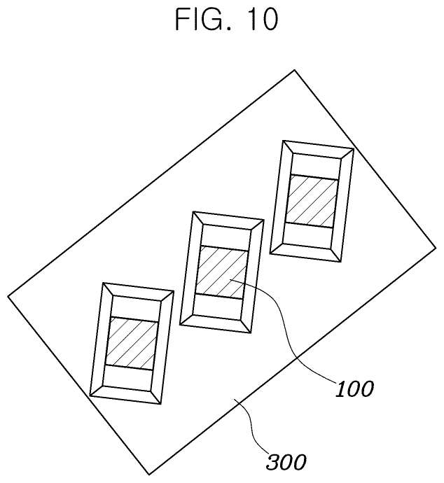

Although the embodiment in which edges of the connector pin 100 are supported has been illustrated, an embodiment in which surfaces of the connector pin 100 are supported, as shown in FIG. 10 is also possible. In the embodiment in which edges of the connector pin 100 are supported, edges of the connector pin 100 respectively supported by the upper insertion hole 310 or the lower insertion hole 330 may have a diagonal relation in that the edges diagonally oppose each other.

In the embodiment in which surfaces of the connector pin 100 are supported, as shown in FIG. 10, surfaces of the connector pin 100 supported by the upper insertion hole 310 or the lower insertion hole 330 may have a facing relation in that the surfaces face each other.

That is, in the embodiment in which edges of the connector pin 100 are supported, edges respectively having a diagonal relation may be supported by the lower insertion hole 330 or the upper insertion hole 310, whereas, in the embodiment in which surfaces of the connector pin 100 are supported, facing surfaces, rather than adjacent surfaces, may be supported by the lower insertion hole 330 or the upper insertion hole 310.

In the embodiment in which surfaces of the connector pin 100 are supported, the area of the connector pin contacting each contact portion of the upper insertion hole 310 and the lower insertion hole 330 is greater than that of the embodiment in which edges of the connector pin 100 are supported and, as such, reliability of fixing of the connector pin 100 may be secured. In addition, even when vibration is generated in a power conversion device in which the power module is used, there is an advantage in that robustness against vibration may be secured in accordance with (e.g., excellent) fixing force.

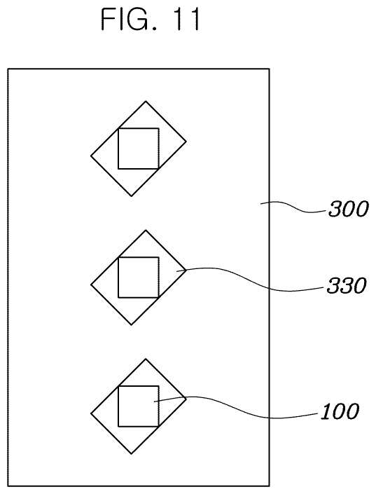

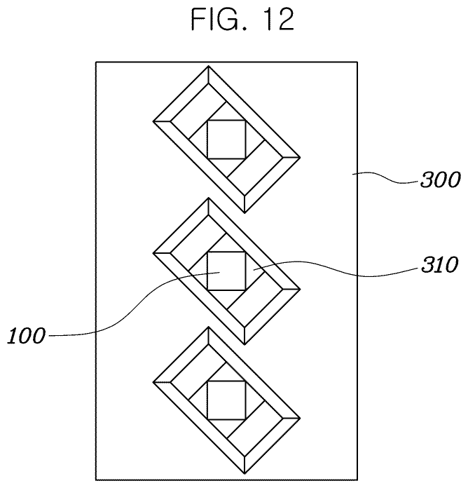

Meanwhile, a series of procedures of inserting the connector pin 100 into the insertion holes will be briefly described with reference to FIGS. 11 and 12.

First, facing edges of the connector pin 100 are supported by the lower insertion hole 330, and two remaining edges of the connector pin 100 are not supported by the lower insertion hole 330. The edges not supported by the lower insertion hole 330 are supported by the upper insertion hole 310. Insertion of the connection pin 100 into the lower insertion hole 330 may be easily carried out, so long as the facing edges are disposed at correct positions, respectively.

Referring to FIGS. 3, 11, and 12, the upper insertion hole 310 and the lower insertion hole 330 are spaced apart from each other in a vertical direction, and are formed in crossing directions, respectively. Accordingly, an overlap portion may be formed between the upper insertion hole 310 and the lower insertion hole 330. The cross-sectional area of the overlap portion between the upper insertion hole 310 and the lower insertion hole 330 may be smaller than the cross-sectional area of the upper insertion hole 310 or the lower insertion hole 330.

The cross-sectional area of the overlap portion between the upper insertion hole 310 and the lower insertion hole 330 may be greater than or equal to the cross-sectional area of the connector pin 100. For example, in the embodiment in which edges of the connector pin 100 are supported, the cross-sectional area of the overlap portion between the upper insertion hole 310 and the lower insertion hole 330 may be greater than the cross-sectional area of the connector pin 100, as shown in FIG. 9. In addition, in the embodiment in which surfaces of the connector pin 100 are supported, the cross-sectional area of the overlap portion between the upper insertion hole 310 and the lower insertion hole 330 may be (e.g., substantially) equal to the cross-sectional area of the connector pin 100, as shown in FIG. 10.

Meanwhile, a slope 350, which is formed to be inclined inwards to guide an initial insertion direction of the connector pin 100, may be formed at at least one of the upper insertion hole 310 or the lower insertion hole 330. The slope 350 may perform a function for absorbing a tolerance possibly generated in an assembly process. To this end, it is preferred that the slope 350 be formed to have a greater cross-sectional area than that of each contact portion.

Even when the position of one of the connector pins 100 is misaligned by a (e.g., certain) degree, the misaligned connector pin 100 may be guided to a correct position while contacting the slope 350 and, as such, a tolerance may be absorbed.

In addition, a space 320 may be formed at a middle portion of the pin holder 300 between the upper and lower surfaces of the pin holder 300. The space 320 may reduce the weight of the pin holder 300, and may enable heat generated at the connector pins 100 to be easily dissipated.

Meanwhile, a power module according to another embodiment of the present disclosure may include a connector pin 100 configured to receive an electrical signal, and a pin holder formed, at upper and lower surfaces thereof, with an upper insertion hole 310 and a lower insertion hole 330, respectively, wherein each of the upper insertion hole 310 and the lower insertion hole 330 supports one surface of the connector pin 100 and an edge of the connector pin 100 facing the surface to regulate an insertion direction of the connector pin 100, and the surface and the edge supported by the upper insertion hole 310 are different from the surface and the edge supported by the lower insertion hole 330, respectively.

In the other embodiment of the present disclosure, it may be possible to compositely support the connector pin 100 through an edge-surface support structure and an edge-surface support structure, rather than an edge-edge support structure and a surface-surface support structure. For example, when connector pin 100 has a triangular shape or a pentagonal shape, it may be possible to support the connector pin 100 through a composite edge-surface support structure by appropriately varying the shapes of the upper insertion hole 310 and the lower insertion hole 330.

When the composite edge-surface structure is employed, as in the above-described embodiment, advantages in both the edge support structure and the surface support structure may be obtained.

In the power module according to the present disclosure, through the pin holder, which has a layered structure, it may be possible to securely regulate an insertion direction of the connector pins. Accordingly, even when the number of connector pins to be assembled to a board is increased, the connector pins may be (e.g., correctly) positioned at positions at which the connector pins are to be assembled to the board. Accordingly, automatic assembly of the power module may be achieved.

In addition, there is (e.g., substantially) no damage to the board and the connector pins caused by erroneous positioning of the connector pins. Accordingly, production of a power conversion device may be (e.g., efficiently) achieved.

Effects attainable in the present disclosure are not limited to the above-described effects, and other effects of the present disclosure not yet described will be more clearly understood by those skilled in the art from the above detailed description.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A power module comprising:
a connector pin configured to receive an electrical signal; and
a pin holder formed having an upper surface with an upper insertion hole configured to receive the connector pin and a lower surface with a lower insertion hole configured to receive the connector pin,
wherein each of the upper insertion hole and the lower insertion hole surface-contacts or line-contacts surfaces or edges of the connector pin, thereby supporting the connection pin inserted into at least one of the upper insertion hole or the lower insertion hole while regulating an insertion direction of the connector pin, and surfaces or edges of the connector pin supported by the upper insertion hole are different from surfaces or edges of the connector pin supported by the lower insertion hole.

2. The power module according to claim 1, wherein the surfaces of the connector pin supported by the upper insertion hole or the lower insertion hole face each other.

3. The power module according to claim 1, wherein the edges of the connector pin supported by the upper insertion hole or the lower insertion hole have a diagonal relation.

4. The power module according to claim 1, wherein the connection pin has a quadrangular cross-sectional shape.

5. The power module according to claim 1, wherein the upper insertion hole or the lower insertion hole has a quadrangular cross-sectional shape.

6. The power module according to claim 1, wherein a cross-sectional area of an overlap portion between the upper insertion hole and the lower insertion hole is smaller than a cross-sectional area of the upper insertion hole or the lower insertion hole.

7. The power module according to claim 1, wherein a cross-sectional area of an overlap portion between the upper insertion hole and the lower insertion hole is greater than or equal to a cross-sectional area of the connector pin.

8. The power module according to claim 1, wherein a slope is formed at at least one of the upper insertion hole or the lower insertion hole to be inclined inwards to guide an initial insertion direction of the connector pin.

9. The power module according to claim 8, wherein the surfaces or the edges of the connector pin are supported by contact portions of the upper insertion hole or the lower insertion hole, and each of the contact portions has a cross-sectional area smaller than or equal to a cross-sectional area of the slope.

10. The power module according to claim 1, wherein a plurality of upper insertion holes and a plurality of lower insertion holes are formed at the upper and lower surfaces of the pin holder.

11. The power module according to claim 1, wherein a space is formed at a middle portion of the pin holder between the upper and lower surfaces of the pin holder.

12. A power module comprising:
a connector pin configured to receive an electrical signal; and
a pin holder formed with an upper surface and a lower surface, the upper surface with an upper insertion hole and the lower surface with a lower insertion hole,
wherein each of the upper insertion hole and the lower insertion hole supports one surface of the connector pin and an edge of the connector pin facing the surface to regulate an insertion direction of the connector pin, and the surface and the edge of the connector pin supported by the upper insertion hole are different from the surface and the edge of the connector pin supported by the lower insertion hole.
